(19) United States
(12) Patent Application Publication
(10) Pub. No.: US 2003/0235989 A1
(43) Pub. Date: Dec. 25, 2003

(54) Process for CMP assisted liftoff

(75) Inventor: Sethuraman Jayashankar, Pittsburgh, PA (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Seagate Technology LLC, Scotts Valley, CA (US)

(21) Appl. No.: 10/361,740

(22) Filed: Feb. 10, 2003

Related U.S. Application Data
(60) Provisional application No. 60/391,534, filed on Jun. 25, 2002.

(51) Int. Cl. H01L 21/302; H01L 21/461; H01L 21/44

(52) U.S. Cl. 438/691; 438/670

(57) ABSTRACT

A method for removal of resist structures used in liftoff patterning of submicron features on structure surfaces, wherein the method does not adversely affect the control of structure thickness nor damage the structure surfaces. The technique comprises the use of a liftoff fluid for solvating the resist, wherein the fluid is assisted by chemical mechanical polishing.

### CROSS-REFERENCE TO RELATED APPLICATION

This application claims priority from Provisional Application No. 60/391,534 filed Jun. 25, 2002, for “SLURRY COMPOSITION FOR CMP ASSISTED LIFTOFF”by S. Jayashankar.

### BACKGROUND OF THE INVENTION

The, present invention generally relates to an improvement to methods of patterning metal, and dielectric submicron structures. More specifically, the, present invention relates to a process utilizing a liftoff fluid during chemical mechanical planarization (CMP) to assist in liftoff of resist used to define features smaller than about one micrometer.

In the field of photolithography, resist application and liftoff patterning processes are known in the art of patterning structures. Liftoff patterning is a general process that is used to define. structures on the surface of a wafer, for example to define features part of which at least one dimension of which would be a submicron structure. The liftoff process typically involves the application or deposition of resist material, followed by a sequence of other processes, including but not limited to: exposure, development, metal or dielectric deposition, and subsequent removal of the resist protective layer, in order to pattern a submicron structure on a substrate. Traditionally, liftoff patterning has been used in defining structures when the use of chemical or plasma etching is undesirable or when such etching is incompatible with the materials and processes involved. Additionally, liftoff patterning is employed when tight line width control (control of dimensional tolerance) is required. Liftoff patterning is commonly used to protect portions of underlying structure from deposition of additional material.

Multilayer magnetoresistive read sensors, including MR, GMR and TMR type sensors, are an example of submicron structures with fabrication processes requiring tight dimensional control. For example, a multilayer read sensor requires tight control of the separation distance between the top and bottom shields because this distance defines the linear recording density of the disk. In the fabrication of multilayer read sensors, four processes affect the dimensional tolerances of the shield-to-shield spacing: deposition of the layers: making up the stack, cap and barrier layer; patterning of the stack by application: of resist followed by a subtractive ion beam milling process; ion beam deposition of the contact insulator (alumina); and liftoff and removal of the resist.

The quality of the liftoff process affects the shield-to-shield spacing as well as the quality and function of the multilayer read sensor being produced. For example, operation and sensitivity of a multilayer read sensor is influenced by the geometry of the stack, including the thickness of the stack and shield-to-shield spacing. The distance between the top and bottom shield is determined by the thickness of the sensor stack layers and the contact insulator thickness. Therefore, the liftoff process must remove the resist material without deleteriously affecting the thickness of the sensor stack (including the cap layer) or the contact insulator. In addition, the thickness and integrity of the contact insulator and cap layer need to be maintained and controlled accurately during the entire fabrication process in order to electrically isolate the top and bottom shields, tightly control the linear density and protect the sensors from corrosion during processing.

The surface topography of the layers is also critical since failure to achieve uniform layer thickness could impact performance of the sensor. The topography and surface roughness of the interface between the film layers adjacent to the read sensor stack affects the exchange coupling. Therefore those characteristics are important to the overall stability of the multilayer read sensor. Incomplete removal of resist and excess portions of applied overlayers (film) may cause topographic variations. Aggressive liftoff techniques may remove excessive material beyond the resist, including contact insulator and stack, deleteriously introducing additional topographic variation. Therefore liftoff methods must completely remove excess material without damaging or corroding the underlying sensor structure. Failure to do so can seriously affect the functionality of the submicron structurebeing fabricated.

An additional problem with conventional liftoff techniques is the inability to clear the detached resist from. the underlying structure. The traditional solvent, e.g. NMP, combined with ultrasonification utilizes gravitational forces to clear the lifted off features from the surface of the underlying structure. These techniques are effective for feature sizes at approximately 1 micrometer and above. However, at feature sizes at 1 micrometer and below the liftoff efficiency of conventional methods decreases drastically in the regime where Van der Waals forces are dominant and.exceed the ultrasonification-applied mechanical forces by orders of magnitude.

The preceding discussion presents the need to develop an improved method of liftoff patterning of submicron structures, including the need for an improved liftoff method with tight dimensional.

Chemical mechanical polishing (CMP) has been previously used in the fabrication of multilayer integrated circuit devices in order to achieve highly planar surfaces suitable for photolithographic patterning of complex circuit; patterns. Material is thereby removed during CMP by a combination of chemical attack and mechanical abrasion. Conventional CMP processes, such as that used to remove material in order to planarize SiO₂ or Si₃N₄ or alumina film on semiconductor wafers, have a material removal rate of 3,000 Å to 5,000 Å per minute under normal process conditions. Even with a significant reduction in polish pressure on the wafer surface (i.e. downforce), the polish rate of a conventional CMP system is still on the order of 1,000 Å per minute.

If conventional CMP polishing is applied to a multilayer read sensor, it can be appreciated that even when the liftoff process is carried out for a period of 15 seconds, the conventional CMP process removes about 250 Å of material, which is a significant fraction of the shield-to-shield spacing of 1,000 Å or less. Consequently, conventional CMP processes are not readily applicable for utilization. as a resist liftoff process where -material removal must be carefully controlled and the underlying structures are vulnerable.

The typical CMP slurries present another complication barring the use of conventional CMP processes in the fabrication of submicron structures. Conventional CMP uses a slurry typically containing abrasive particles and reagents for chemically and mechanically reacting with the surface of the wafer. When multilayer read sensors are exposed to. typical CMP slurries, the slurry chemistry causes severe corrosion in the sensor elements.

Therefore there is a continuing. need for an improved liftoff process for use with liftoff patterning of submicron structures that causes minimal loss of the layered structure. For example, in the multilayer read sensor, liftoff of the resist should minimize losses to the contact insulator (alumina) and cap layer thickness of the magnetoresistive stack, while effectively removing the resist material and excess alumina attached to the resist. It is also desirable that the liftoff process not cause corrosion of any components of the multilayer read sensor during processing and that the underlying multilayer read sensor structure remains intact without disruption of the surfaces of the magnetoresistive layers.

### BRIEF SUMMARY OF THE INVENTION

The liftoff process of the invention effectively removes resist structures covering at least a portion of a structure surface without removing excessive material or otherwise damaging the structure surface. The liftoff process is applicable to, but not limited to resist removal from submicron features on structure surfaces. The liftoff process comprises liftoff of the resist utilizing a fluid composition without abrasive particles assisted by a low-pressure chemical mechanical polishing technique. The properties of the CMP-assisted fluid include solvation of the resist material, surfactant abilities, corrosion inhibition and a pH of between 7 .and 11. The abrasives commonly used in conventional CMP slurries are not present in the CMP-assisted fluid. The fluid is effective for the removal of electron beam applied resist, as well as, resist covered-with layers of either reactively sputtered alumina or ion beam deposited alumina.

### BRIEF DESCRIPTION OF THE DRAWINGS

FIG. 1 is a flow chart of a liftoff patterning process including CMP-assisted liftoff.

FIG. 2 is a sectional view of a partially formed multilayer read sensor structure following deposition of a resist layer.

FIG. 3 is a sectional view of a partially formed multilayer read sensor structure after resist development.

FIG. 4 is a sectional view of a partially formed multilayer read sensor structure after definition of the stack.

FIG. 5 is a sectional view of a partially formed multilayer read sensor after deposition of a contact insulator layer.

FIG. 6 is a sectional view of a partially formed multilayer read sensor after removal of the resist by CMP assisted liftoff.

### DETAILED DESCRIPTION

The present invention is an improved method for liftoff and removal of resist with tight dimensional control for the formation of submicron patterned structures. More specifically, the invention involves removal of resist structures during liftoff patterning processes used in the fabrication of submicron structures such as multilayer read sensors. The liftoff patterning process is described in the context of defining a feature of a multilayer read sensor, with the described process and problems being also applicable to other submicron structures and features.

Liftoff patterning of structures with critical dimensions (CD's) below 1 micrometer introduces new challenges, more so when tight line width control is required. For example, the shield-to-shield spacing Qn a multilayer read sensor is presently on the order of 1000 Å [100 nm]. For areal densities of hard disk storage approaching 1 Tb/in², the separation distance between the top and bottom shields of the multilayer read sensor will need to be on the order of 700Å [70 nm] or less. The active stack of multilayer read sensors will also now, require being fabricated at critical dimensions of 200nm or smaller. For these and other submicron structures, conventional UV photolithography is not capable of adequately defining features in this size range. Rather, techniques such as electron-beam (e-beam). lithography are needed where an electron beam, source is used to write the pattern directly into a resist layer to achieve the, necessary -submicron feature dimensions. The inventive techniques described herein are suitable for patterned features narrower than 10 micrometers [10,000 nm], preferably narrower than 1 micrometer [1000 nm] and most preferably less than 200 nanometers.

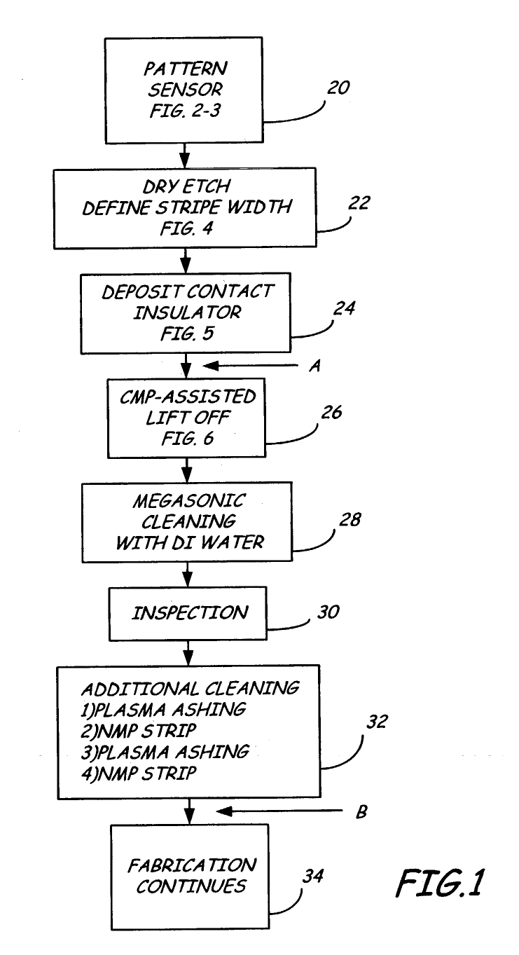

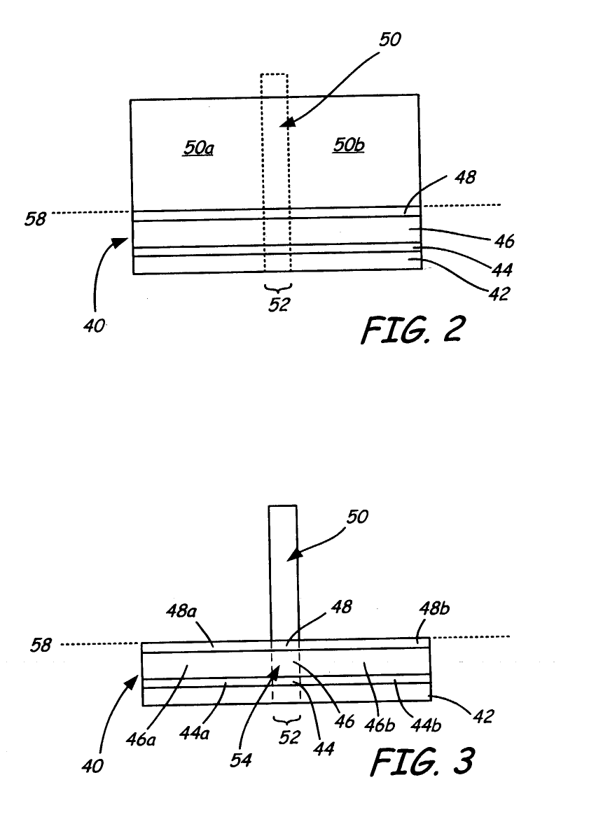

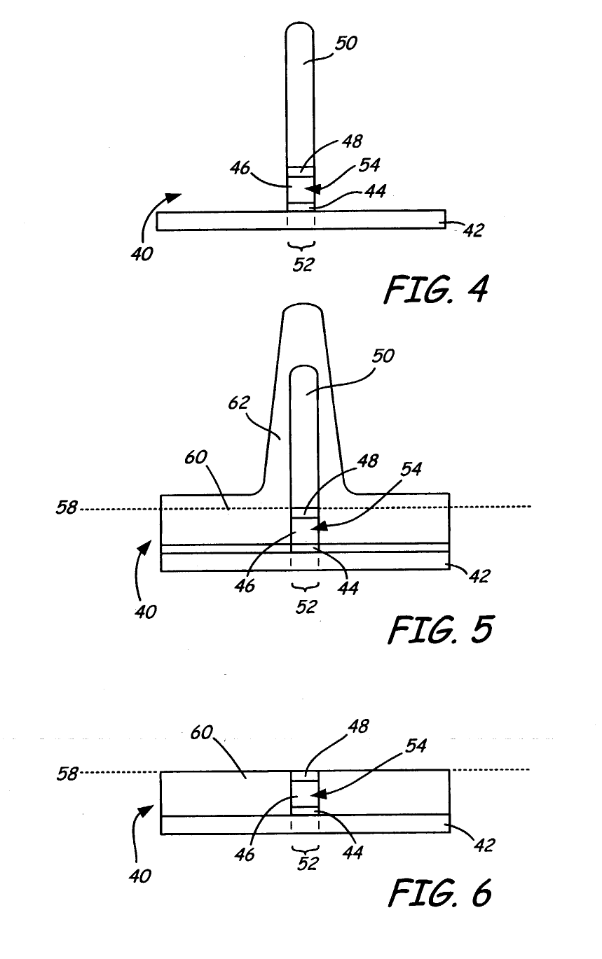

An overview of liftoff patterning, including the inventive liftoff process, used to define the magnetoresistive stack of a multilayer read sensor is provided by the flowchart shown in FIG. 1. Step 20 in the flowchart is patterning the sensor. A pattern is created in resist to isolate a region that will correspond to the magnetoresistive stack in the completed read sensor. Further description. is found in FIGS. 2 and 3. Step 22 is the definition of the stripe width of the magnetoresistive stack by dry etching, which is further described in FIG. 4. Step 24 corresponds to the deposition of a contact insulator layer, further described in FIG. 5. Now, in step 26, the inventive CMP-assisted liftoff occurs. This process is additionally shown in FIGS. 5 and 6. CMP-assisted liftoff is followed by megasonic cleaning with deionized water or other suitable solvent (step 28). Inspection of the structure occurs in step 30. Additional cleaning is represented in step 32, including alternating steps of plasma ashing and stripping with the solvent NMP. Additional steps 34 to complete the fabrication of the multilayer read sensor follow the completion of the formation of the magnetoresistive stack.

A more detailed description of the liftoff patterning process, coinciding with the flowchart in FIG. 1 is given below and illustrated in FIGS. 2-6.

FIG. 2 illustrates a partially formed structure 40 for a multilayer read sensor. The read sensor is one of several thousand like structures carried by a support, for example a 6 inch diameter wafer, through many steps of the fabrication process. The support is omitted from the figures for clarity. Initial fabrication steps for structure 40 including: deposition of a diffusion barrier 44 on bottom shield 42, followed by deposition of multiple layers corresponding to the magnetoresistive materials 46, followed by deposition of the cap layer 48, are completed.

The next step in the continuing fabrication of the multilayer read sensor is the shaping of the magnetoresistive stack 54 (FIG. 3). The magnetoresistive stack is formed from the already deposited layers: the diffusion layer 44, magnetic materials 46, and cap layer 48 through the use of liftoff patterning in combination with other techniques. The first step 20 in liftoff patterning begins with deposition of resist material 50. FIG. 2 shows the deposited resist layer 50 covering the cap layer 48 of structure 40. Subsequent to deposition of the resist 50, an electron beam source patterns the resist 50 over area 52 that contains what will become the magnetoresistive stack 54. The resist 50 is cross-linked where exposed to the electron beam, which makes the resist material more resistant to salvation by a developer solution. Following exposure of resist 50 in area 52 to the electron beam, development of the resist by application of a developer solution removes regions 50a and 50b resulting in the structure seen in FIG. 3. In this demonstration, resist 50 is a negative type resist, for example NEB-31 made by Sumitomo.

Either negative or positive type resists may be, used for patterning submicron features. For techniques involving negative resists, the exposed area remains on the structure after development as seen in FIG. 3. In contrast, for positive resists the area exposed to the electron beam becomes more susceptible to the developer solution and is removed during the development process. A suitable positive e-beam resist is UV-113 manufactured by Shipley. The inventive liftoff processing is equally applicable to features patterned using either positive and negative resists. While primarily directed to liftoff processinrg of submicron features-patterned by e-beam resists, the inventive process may also be applied to the removal of conventional UV resists used in the patterning of larger features.

In FIG. 3, patterning of the stack 54 has been performed, so that a resist column 50 stands over area 52. Resist structures, such as resist column 50, are applied to protect regions, such as area 52 from additive processes, subtractive processes or a combinations of both. Common additive processes include, but are not limited to, ion beam deposition, reactive sputtering, other sputtering techniques such as radio frequency (RF) and magnetron sputtering, and chemical vapor deposition (CVD). Subtractive processes include, but are not limited to, ion beam etching or reactive ion milling.

Step 22 (of FIG. 1) is the definition of the stripe width of the magnetoresistive stack 54 by dry etching. The resist column 50 allows the definition of the stack 54, including layers 44, 46 and 48 within area 52. The material of structure 40 not protected by the resist structure 50 is removed by a subtractive process, in this case, dry etching. The subtractive process, for example ion beam milling or etching, causes the width of the stack 54 to correspond to the width of the resist 50 by removing excess stack material, namely regions 48a and 48b, 46a and 46b, and 44a and 44b shown previously in FIG. 3. The resulting structure 40 of FIG. 4 shows stack 54 and the resist 50 subsequent to definition. As can be seen, subtractive processes such as ion beam milling can cause secondary damage to the resist 50, resulting in a rounded profile as shown in FIG. 4 or an undesirable positive sloped profile.

The structure 40 is now prepared for the deposition of additional elements, including contact insulator 60 (described as step 24 in FIG. 1) and as shown in FIG. 5. The contact insulator 60 may be ion beam deposited or reactively sputtered aluminum oxide (alumina). In this process, the contact, insulator 60 deposited on the shield 42 is desired to have a thickness equal to the thickness of the stack 54 including cap layer 48. However, a sidewall 62 of contact insulator has also been deposited on the resist 50 as shown in FIG. 5. The covering of the resist structure 50 with deposited contact insulator 60 can, be the result of both non-collimated deposition and changes in the-profile of the resist 50 caused by subtractive processes in the preceeding stage. Structure 40 is now ready for the step 26 (of FIG. 1), liftoff and removal of the resist material 50, along with sidewall 62.

The coating of all sides of the resist structure in addition to the underlying structure 40 by the deposited contact insulator causes two problems for conventional liftoff techniques which generally rely on solvents in tandem with ultrasonification to aid diffusion. First, the efficiency of the liftoff process is inhibited by poor access of the solvent to the encapsulated resist material. Second, excess material may remain attached to the structure after liftoff causing unwanted electrical short circuiting, topography changes, and thickness variations.

The conventional liftoff processes employed “reentrant” resist profiles to create breaks in the film to aid solvent access to the resist structure during liftoff. A-commonly used technique is bilayer resists to create overhangs or undercuts in the resist profile. However, the techniques of bi-layer resists and overhang resist profiles utilized to achieve efficient liftoff in conventional photolithography are more difficult to achieve with e-beam lithography because of the smaller critical dimensions and the tight process tolerances. Also, changes in resist profiles, for example undercuts on bi-layer resists, may adversely affect the structural integrity of resist. Therefore the prior techniques are less effective for removal of resist and attached materials as the size of the features and structures decrease to the submicron level.

The inventive CMP assisted liftoff technique was developed to overcome the liftoff problems associated with patterned submicron features. The inventive CMP assisted liftoff provides solvent access and effective separation of the resist structure from the sensor. Another improvement is the facilitation of removal of the lifted-off structures away from the underlying sensor structure.

For the CMP-assisted liftoff process, the structure 40 is mounted to the table of a conventional CMP polishing machine, for example the 6EC and 6DS-SP models from Strasbaugh, a Mirra polisher manufactured by Applied Materials, or other suitable CMP polishing machines such as those Ebara, Lam Research or Speedfam-Ipec. The structure 40 is then subjected to a flow of liftoff-fluid of between 100 ml/min to 500 ml/min, more preferably between approximately 150 ml/min to 300 ml/min. The liftoff fluid assists in removing the resist 50 and sidewall 62 of contact insulator 60 as the wafer surface is subjected to low pressure contact with a CMP polishing pad,for short time intervals. The range of downforce is in the range from 0 to 20 psi. Preferably, the downforce applied is in the range of approximately 0 to 7 psi. Most preferably, the downforce applied is in the range of approximately 0 to 3 psi. The low downforce and the wafer rotation result in the clean shearing of the sidewall alumina along the top surface of the contact insulator.

A CMP-assisted process suitable for removal of ion beam deposited alumina from the multilayer read sensors contained by a wafer is composed of three sequential steps. Step 1: The polish table holding the polish pad is rotated at 35 rpm. The wafer carrier holding the active wafer surface containing the multilayer read sensor structures exposed and facing downward is rotated at 10 rpm. The active wafer surface is subjected to a downforce of 1 psi against the polish pad for 10 seconds with a liftoff fluid flow of 200 mL/min. Step 2: The polish table is rotatedtat 70 rpm. The wafer carrier is rotated at 20 rpm. The active wafer surface is subjected to a downforce of 3 psi for 10 seconds with a liftoff fluid flow of 250 ml/min. -Step 3: The polish table is rotated at 70 rpm and the wafer carrier is rotated at 20 rpm. The active wafer surface is subjected to a downforce of 3 psi for 10 seconds with a liftoff fluid flow of 250 ml/min.

CMP assisted liftoff results in the structure shown in FIG. 6. As demonstrated, the removal of contact insulator is minimized, with adequate control of removal to stop at approximately line 58. CMP assisted liftoff exposes the cap layer 48 in preparation for deposition of the top shield (not shown) without damaging the stack 54 while achieving the desired shield-to shield spacing.

The process parameters above may vary in number of steps, rotation speed of the table and polishing pad, pressure applied, and time of contact based on the thickness, area coverage. and other characteristics of the resist structures and sidewall material. Suitable CMP assisted liftoff pads include IC 1400 K-Grv pads, IC 1000, Suba 4, and Politex. Other polishing pads may be utilized as are known in the art.

The brief application of the CMP polishing pad against the wafer surface aids the liftoff fluid by shearing the sidewall layer of alumina and by separating and carrying away the lifted off resist features from the surface of the sensor. The CMP-assisted liftoff technique results in very controlled removal of a very small thickness of material on the order of 100 Å or less. This loss rate is within acceptable process limits. Minimal thickness change in the contact insulator layer of the multilayer read sensor is critical to achieving controlled shield-to-shield spacing.

The control of the critical dimensions within desired tolerances during the liftoff process is achieved by the chemistry of the liftoff fluid rather than reliance solely on mechanical removal ,of the resist. The composition of the liftoff fluid is characterized: by the ability to dissolve the resist structure while not attacking the structure 40, including contact insuilator 60 or other features commonly found in read sensors and like structures as are known in the art. Specifically, the liftoff fluid should not cause corrosion of metallic components, for example, copper components of stack 54. The liftoff fluid should easily wet the polishingepads and have a lowered surface tension to penetrate the resist structures during liftoff. Additionally, pH of the liftoff fluid should be optimized for desired solvation and to aid in easy removal of debris from the wafer surface. Also, as described above, the liftoff fluid should not cause excessive removal (high etch rate) of the contact insulator and should preferably not contain an abrasive component so as to maintain control of the contact insulator thickness during CMP liftoff.

The liftoff fluid is preferably a solution with a pH value between approximately pH 7 and approximately pH 11, wherein the resist material is soluble in the alkaline solution. Most preferably the liftoff fluid is an aqueous solution with a pH value between approximately pH 7 and approximately pH 2 0 1 1, wherein the resist material is soluble in the aqueous, basic solution. A basic solution pH creates negative surface potentials on the surface of the contact insulator, the liftoff debris, and the read sensor surface, which aids removal of the debris from the read sensor. The upper limit of preferably approximately pH 11 is to prevent corrosion of copper features such as are found in some read sensors.

Any basic solution is a suitable candidate with the exception of those solutions with the potential to cause damage to metallic components. For example, solutions that contain chemistries readily forming complexes with copper cannot be used where the submicron structure contains copper features, such as copper layers within the stack of a multilayer read sensor. The formation of complexes with copper will lead to increased susceptibility to corrosive damage from solvent exposure. For example, suitable bases include NaOH, KOH, and tetramethyl ammonium hydroxide, while ammonium hydroxide would not be suitable for liftoff solutions for use with structures having copper containing features.

The surface wetting agent may be any non-ionic surfactant that is soluble in the liftoff fluid and compatible with the polishing pads. Suitable surfactants include Triton X-100 and Surfynol-61.

Additionally a corrosion inhibitor may be added to the liftoff fluid. Suitable corrosion inhibitors include: benztriazole, polyphosphates, carboxylic acids, oximes, P-diketones, thiourea, tannin, gelatin and saponin.

The fluid composition will preferabfy not include abrasive particles which are commonly included in conventional CMP. For purposes of this application, abrasive particles, are defined as particles included during CMP to increase mechanical forces applied to the surface being polished. These particles are typically insoluble in the fluid composition. Conventional abrasives include: SiO3, A1203, CeO2, SnO2, ZrO2, other metal oxides, organic polymers or particles coated with polymers.

The present invention is more particularly described in the following examples.

### EXAMPLE 1

The first example liftoff fluid includes:

3 ml of 50% NaOH solution

22.5 ml ofTriton X-100

5 g Benztriazole

15 L deionized water

Table 1 represents the contact insulator thickness distributions of different wafers processed using the first example liftoff fluid. The pre-liftoff contact insulator measurements and post-liftoff contact insulator measurements were taken at arrows A and B respectively as seen in the flowchart of FIG. 1. Wafers #606 and #639 had reactive sputtered alumina as the contact insulator layer. Wafers #604 and #622 had ion beam deposited alumina as the contact insulator layer.

TABLE 1

| | | Pre-liftoff | | | Post-liftoff | | |
|---|---|---|---|---|---|---|---|
| | | Contact | | | Contact | | Thickness |
| | | Insulator | | | Insulator | | Of Material |
| Wafer | | Thickness | Std. | | Thickness | Std. | Removed |
| Name | N | Mean (Å) | Dev | N | Mean (Å) | Dev. | (Å) |
| 604 | 8 | 1402.8 | 11.3 | 6 | 1314 | 19.2 | 88.8 |
| 606 | 5 | 1857.7 | 36.1 | 5 | 1786.2 | 36.4 | 71.5 |
| 622 | 10 | 1749.7 | 20.7 | 6 | 1722 | 10.9 | 27.7 |
| 639 | 5 | 1854.7 | 40.5 | 5 | 1785 | 35.5 | 69.7 |

### EXAMPLE 2

The second example liftoff fluid includes:

60 ml of a 25% solution of tetramethyl ammonium hydroxide

10 g Benztriazole

15 ml Triton X-100

15 L deionized water

Table 2 represents the contact insulator thickness of individual sensors measured at locations on the surface of a wafer. The contact insulator thickness was measured before liftoff processing and after CMP assisted liftoff using the second example liftoff fluid. The measurements were taken at arrows A and B respectively as seen in the flowchart of FIG. 1.

TABLE 2

| | | Pre-liftoff | Post-liftoff | Material |
|---|---|---|---|---|
| Wafer | Location | Contact Insulator | Contact Insulator | Removed |
| Name | Name | Thickness (Å) | Thickness (Å) | (Å) |
| 619 | B | 907 | 888 | 19 |
| | C | 929 | 903 | 26 |
| | D | 935 | 888 | 47 |
| 623 | A | 888 | 853 | 35 |
| | B | 997 | 896 | 101 |
| | C | 957 | 914 | 43 |
| | D | 940 | 905 | 35 |
| | E | 969 | 912 | 57 |
| 636 | A | 495 | 455 | 40 |
| | B | 541 | 476 | 65 |
| | C | 504 | 526 | (22) |
| | D | 545 | 504 | 41 |
| | E | 590 | 468 | 122 |

Following removal of the resist structure 50 and sidewall 62 by the CMP-assisted liftoff, the structure 40 may under go further cleaning steps. Examples include the application of resist developer solutions, e.g. NMP, or plasma ashing of remaining debris. The additional cleaning steps may be performed to insure complete removal of organic residues before deposition of the upper contact/shield layer or other features as known in the art to complete the read sensor structure 40.

In conclusion, the device fabrication process utilizes an inventive CMP assisted liftoff process to successfully remove resist structures from submicron features without damaging the underlying structure. Although, the inventive technique is taught in the context of a multilayer read sensor structure, the techniques taught may be applied to known methods of fabrication for other submicron structures including nanodevices and semiconductor-based nanodevices. Although the present invention has-been described with reference to preferred embodiments, workers skilled in the art will recognize that changes may be made in form and detail without departing from the spirit and scope of the invention.

1. A resist liftoff process comprising:
covering at least a portion of a structure surface with a resist; and
producing liftoff of the resist by low pressure chemical mechanical polishing utilizing a fluid composition without abrasive particles.

2. The process of claim 1, wherein the fluid composition comprises a solvent for the resist, a surfactant, and a corrosion inhibitor.

3. The process of claim 2, wherein the solvent is water and the pH of the composition is between approximately 7 and approximately 11.

4. The process of claim 2, wherein the surfactant is non-ionic.

5. The process of claim 2, wherein the surfactant is chosen from the group consisting of: Triton X-100 and Surfynol-61.

6. The process of claim 2, wherein the corrosion inhibitor is selected from the group consisting of: benztriazole, polyphosphates, carboxylic acids, oximes, P-diketones, thiourea, tannins, gelatin and saponin.

7. The process of claim 1, wherein the process further comprises:
patterning a submicron feature using electron beam definition of the resist prior to producing liftoff.

8. The process of claim 1, wherein the chemical mechanical polishing is performed at pressures less than approximately 7 psi for less than approximately 60 seconds.

9. The process of claim 1, wherein the fluid is applied in a flow rate range from between approximately 150 mL/min to approximately 300 mL/min.

10. A liftoff process for removal of resist from a protected feature of a sub-micron structure, the liftoff method comprising:
applying a non-abrasive fluid composition to the resist; and
assisting, the non-abrasive fluid by low pressure chemical mechanical polishing of the sub-micron structure.

11. The process of claim 10, wherein the fluid composition comprises a solvent for the resist, a surfactant, and a corrosion inhibitor.

12. The process of claim 10, wherein the solvent is water and the pH of the composition is between approximately 7 and approximately 11.

13. The process of claim 10, wherein the surfactant is chosen from the group consisting of Triton X-100 and Surfynol-61.

14. The process of claim 10, wherein the corrosion inhibitor is selected from the group consisting of: benztriazole, polyphosphates, carboxylic acids, oximes, β-diketones, thiourea, tannins, gelatin and saponin.

15. The process of claim 10, wherein the process also comprises patterning the protected feature using e-beam lithography.

16. The process of claim 10, wherein the chemical mechanical polishing is performed at pressures from between approximately zero psi to approximately 7 psi for from approximalty zero seconds to approximately 60 seconds.

17. The process of claim 10, wherein the fluid is applied in a flow rate range, from between approximately 150 mL/min to approximately 300 mL/min.

18. A method for formation of a submicron feature of a multilayer structure using photolithography, the method comprising:
defining a submicron feature using an electron beam and a resist material to form an e-beam resist structure; and
exposing the submicron feature using the steps of:
contacting the structure with a non-abrasive liftoff fluid;
performing chemical mechanical polishing with applied pressure less than 20 psi; and
removing the e-beam resist structure from the structure to expose the submicron feature.

19. The method of claim 18 wherein the submicron feature defined has a width of approximately 200 nm or less.

20. The method of claim 18, wherein the non-abrasive liftoff fluid is composed of a solvent for the resist structure, a surfactant and a corrosion inhibitor.

21. The method of claim 18, wherein the applied pressure of the chemical mechanical polishing is applied to the structure for less than 60 seconds.

22. The method of claim 18, wherein the fluid is applied in a flow rate range from between approximately 150 mL/min to approximately 300 mL/min.

23. A method for formation of a multilayer read sensor, wherein the multilayer read sensor has a stack, the method comprising:
depositing a plurality of layers upon a first shield;
depositing resist over the plurality of layers;
e-beam defining the resist over a portion of the plurality of layers;
developing the resist;
applying a subtractive process to the plurality of layers to form the stack;
depositing a layer around the stack and defined resist;
removing defined resist by applying a non-abrasive fluid composition; and
assisting removal of the defined resist by the non-abrasive fluid by low pressure chemical mechanical polishing.

24. The method of claim 23, wherein the chemical mechanical polishing is performed at pressures less than approximately 7 psi for less than approximately 60 seconds.

25. The method of claim 23, wherein the fluid is applied in a flow rate range from between approximately 150 mL/min to approximately 300 mL/min.

26. The method of claim 23, wherein the fluid comprises a solvent for the resist, a surfactant, and a corrosion inhibitor.
